(19) United States
(12) Patent Application Publication
(10) Pub. No.: US 2007/0085217 A1
(43) Pub. Date: Apr. 19, 2007

(54) Mounting board and semiconductor device

(76) Inventor: Haruo Sorimachi, Nagano-shi (JP)

Correspondence Address: LADAS & PARRY LLP, 224 SOUTH MICHIGAN AVENUE, SUITE 1600, CHICAGO, IL, 60604, US

(21) Appl. No.: 11/542,871

(22) Filed: Oct. 4, 2006

(30) Foreign Application Priority Data
Oct. 13, 2005 (JP) 2005-299206

(51) Int. Cl. H01L 23/48

(52) U.S. Cl. 257/778

(57) ABSTRACT

A mounting board on which a semiconductor chip having multiple connection bumps is to be mounted by flip-chip bonding is disclosed. The mounting board includes multiple connection pads to be electrically connected to the corresponding connection bumps, where the connection pads have respective surfaces coated with solder; and an insulating layer configured to surround the connection pads and isolate the connection pads from each other. Each of the connection pads has a first region and at least one second region to be connected to a corresponding one of the connection bumps. The first region has a surface substantially as high as a surface of the insulating layer and the second region has a surface lower than the surface of the first region.

### BACKGROUND OF THE INVENTION

1. Field of the Invention

The present invention relates generally to a mounting board on which a semiconductor chip is to be mounted by flip-chip bonding and to a semiconductor device having a semiconductor chip mounted on the mounting board.

2. Description of the Related Art

With recent improvements in the performance of semiconductor chips due to the miniaturization of their circuits, mounting boards for mounting semiconductor chips have also been required to have finer wiring. Therefore, various proposals for miniaturization have been made on the structure of connection pads, which are part of the mounting board to be connected to a semiconductor chip. In the following, first, a typical example of the conventional mounting of a semiconductor chip on the mounting board is given, and then a description is given of a structure accommodating the miniaturization of a semiconductor chip on the part of the mounting board.

FIGS. 1A through 1E are diagrams sequentially showing the procedure of a conventional method of mounting a semiconductor chip on a mounting board by flip-chip bonding. FIG. 1A shows a semiconductor chip 1 to be mounted on a mounting board, on which semiconductor chip 1 connection bumps (Au bumps) 2 are formed. For example, the connection bumps 2 are formed by Au wire bonding.

In the process shown in FIG. 1B, the connection bumps 2 are pressed using a flat board, thereby equalizing the heights of the connection bumps 2.

Next, in the process shown in FIG. 1C, the semiconductor chip 1 is mounted on a mounting board 3 having connection pads 4 formed thereon. In this case, the semiconductor chip 1 is mounted on the mounting board 3 so that the connection bumps 2 are in contact with the connection pads 4. Connection parts 5 formed of solder are provided where the connection bumps 2 and the connection pads 4 are in contact with each other so as to ensure the electric connections therebetween.

Next, in the process shown in FIG. 1D, underfill 6 is caused to flow into the space between the mounting board 3 and the semiconductor chip 1 mounted thereon. Further, in the process shown in FIG. 1E, the underfill 6 is present completely through the space between the mounting board 3 and the semiconductor chip 1. Thereafter, the underfill 6 is cured. Thereby, the mounting of the semiconductor chip 1 is completed.

In the above-described mounting of the semiconductor chip 1, if the circuit of the semiconductor chip 1 is further miniaturized (the pitch of the connection bumps 2 becomes finer)., this should be accommodated on the part of the mounting board 3 (connection pads 4).

For example, there is a problem in that the miniaturization of the circuit of a semiconductor chip causes solder used in a connection part of the semiconductor chip and a mounting board to come into contact with solder used in an adjacent connection part, thereby increasing the probability of the occurrence of a short circuit in the circuit of the semiconductor chip. Therefore, for example, a mounting board structure accommodating the miniaturization of a semiconductor chip as shown below is proposed.

FIG. 2A is a schematic perspective view of part of a mounting board 10, which is an example of the mounting board accommodating the miniaturization of a semiconductor chip. FIG. 2B is a cross-sectional view of the mounting board 10 of FIG. 2A taken along the line A-A′.

Referring to FIG. 2A, in the mounting board 10, connection pads 4A to which a semiconductor chip is to be connected by flip-chip bonding are formed on an insulating layer 3A so as to be exposed through the opening of a solder mask layer 7 formed on the insulating layer 3A.

A semiconductor chip is to be connected to the connection pads 4A by flip-chip bonding. Each of the connection pads 4A is made up of a narrow first region 4a and a second region 4b to which a corresponding connection bump of the semiconductor chip is to be connected. The second region 4b is greater in width than the first region 4a.

The surface of each connection pad 4A is coated with solder. When the solder is melted, the melted solder moves from the first region 4a to concentrate in the second region 4b because of its surface tension.

Therefore, it is possible to reduce the thickness of the solder coating layer formed on the first region 4a while ensuring a necessary thickness of the solder coating layer on the second region 4b in the connection pad 4A. Accordingly, it is possible to prevent the solder from short-circuiting adjacent connection parts (see Patent Document 1).

FIG. 3A is a schematic perspective view of part of a mounting board 10A, which is a variation of the above-described mounting board 10. In FIG. 3A, the same elements as those described above are referred to by the same reference numerals, and a description thereof is omitted.

Referring to FIG. 3A, the mounting board 10A is structured by embedding the connection pads 4A in the insulating layer 3A in the mounting board 10 shown in FIG. 2A. The surface of each connection pad 4A is substantially as high as the surface of the insulating layer 3A.

By the above-described structure, melted solder is prevented from spreading to the insulating layer side. FIG. 3B is a cross-sectional view of the mounting board 10A of FIG. 3A taken along the line B-B′. As shown in FIG. 3B, the difference in wettability with respect to solder between the insulating layer 3A and the connection pads 4A prevents melted solder from spreading to the insulating layer side in the mounting board 10A.

Referring back to FIG. 2B, FIG. 2B shows that the solder spreads sideward compared with the case of the mounting board 10A (FIG. 3B). On the other hand, the solder is prevented from spreading sideward in the case of the mounting board 10A shown in FIGS. 3A and 3B, thus preventing the occurrence of a short circuit between adjacent connection parts (see Patent Document 2).

Reference may also be made to Patent Document 3 for related art.

[Patent Document 1] Japanese Laid-Open Patent Application No. 2000-77471

[Patent Document 2] Japanese Laid-Open Patent Application No. 2001-284783

[Patent Document 3] Japanese Laid-Open Patent Application No. 2002-329744

In the case of achieving further miniaturization of the circuit of a semiconductor chip, further accompanying miniaturization of mounting pads, and narrower pitches, however, it may be difficult to prevent the occurrence of a short circuit due to the contact of adjacent solder coatings even with the mounting board 10 or 10A.

In particular, if the pitch of the connection pads is less than or equal to 50 μm, it may be difficult to prevent the occurrence of a short circuit due to solder contact by the above-described methods.

### SUMMARY OF THE INVENTION

Embodiments of the present invention may solve or reduce the above-described problem.

According to one embodiment of the present invention, there are provided a mounting board in which the above-described problem in solved, and a semiconductor device having a semiconductor chip mounted on the mounting board.

According to one embodiment of the present invention, there are provided a mounting board that accommodates the miniaturization of the circuit of a semiconductor chip, and a semiconductor device having a semiconductor chip mounted on the mounting board.

According to one embodiment of the present invention, there is provided a mounting board on which a semiconductor chip having a plurality of connection bumps is to be mounted by flip-chip bonding, the mounting board including: a plurality of connection pads to be electrically connected to the corresponding connection bumps, the connection pads having respective surfaces coated with solder; and an insulating layer configured to surround the connection pads and isolate the connection pads from each other, wherein each of the connection pads has a first region, and at least one second region to be connected to a corresponding one of the connection bumps, the first region having a surface substantially as high as a surface of the insulating layer and the at least one second region having a surface lower than the surface of the first region.

The above-described mounting board allows a semiconductor chip having a miniaturized circuit to be mounted thereon.

According to one embodiment of the present invention, there is provided a semiconductor device including: a semiconductor chip having a plurality of connection bumps; and a mounting board on which the semiconductor chip is mounted by flip-chip bonding, wherein the mounting board includes a plurality of connection pads to be electrically connected to the corresponding connection bumps, the connection pads having respective surfaces coated with solder; and an insulating layer configured to surround the connection pads and isolate the connection pads from each other, wherein each of the connection pads has a first region, and at least one second region to be connected to a corresponding one of the connection bumps, the first region having a surface substantially as high as a surface of the insulating layer and the at least one second region having a surface lower than the surface of the first region.

The above-described semiconductor device allows a semiconductor chip having a miniaturized circuit to be mounted therein.

Thus, according to embodiments of the present invention, it is possible to provide a mounting board accommodating the miniaturization of the circuit of a semiconductor chip and a semiconductor device having a semiconductor chip mounted on the mounting board.

### BRIEF DESCRIPTION OF THE DRAWINGS

Other objects, features and advantages of the present invention will become more apparent from the following detailed description when read in conjunction with the accompanying drawings, in which:

FIGS. 1A through 1E are diagrams showing a mounting method of a conventional semiconductor device;

FIG. 2A is a diagram showing a first conventional mounting board;

FIG. 2B is a cross-sectional view of the first conventional mounting board of FIG. 2A taken along the line A-A′;

FIG. 3A is a diagram showing a second conventional mounting board;

FIG. 3B is a cross-sectional view of the second conventional mounting board of FIG. 3A taken along the line B-B′;

FIG. 4A is a perspective view of a mounting board according to a first embodiment of the present invention;

FIG. 4B is a cross-sectional view of the mounting board of FIG. 4A taken along the line C-C′ according to the first embodiment of the present invention;

FIG. 5 is a schematic cross-sectional view of the entire mounting board of FIG. 4A according to the first embodiment of the present invention;

FIG. 6 is a schematic cross-sectional view of a semiconductor device having a semiconductor chip mounted on the mounting board according to the first embodiment of the present invention;

FIGS. 7A through 7L are diagrams showing a method of manufacturing the mounting board according to the first embodiment of the present invention;

FIGS. 8A through 8E are diagrams showing a method of manufacturing the semiconductor device of FIG. 6 according to the first embodiment of the present invention;

FIG. 9 is a perspective view of the semiconductor device of FIG. 6 according to the first embodiment of the present invention;

FIG. 10 is a perspective view of a mounting board according to a second embodiment of the present invention; and

FIG. 11 is a diagram showing a disposition pattern of bumps of a semiconductor chip to be mounted on the mounting board of FIG. 10 according to the second embodiment of the present invention.

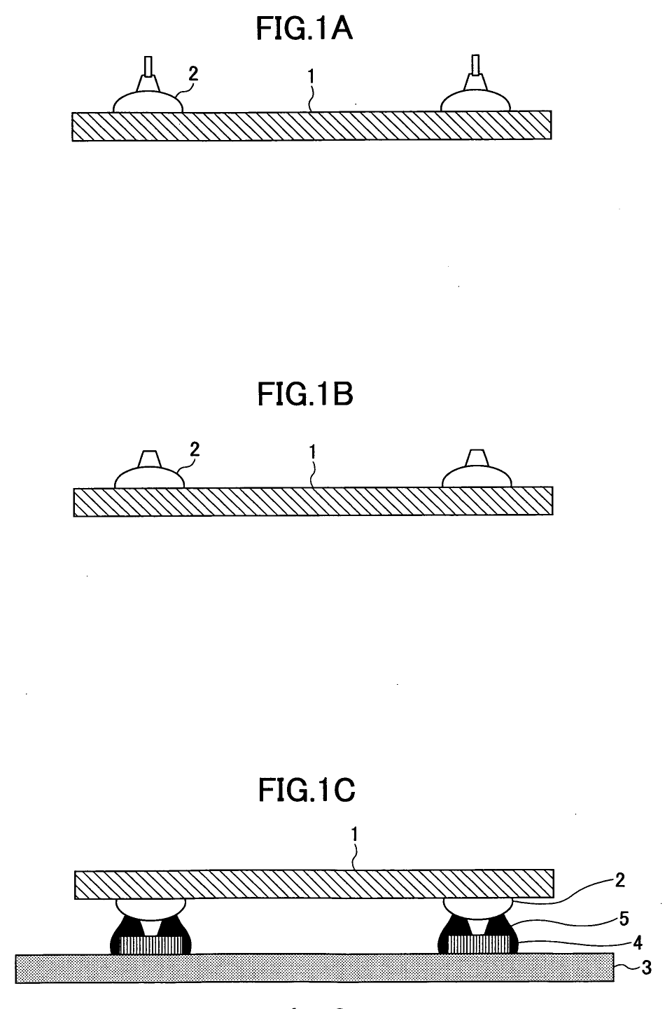

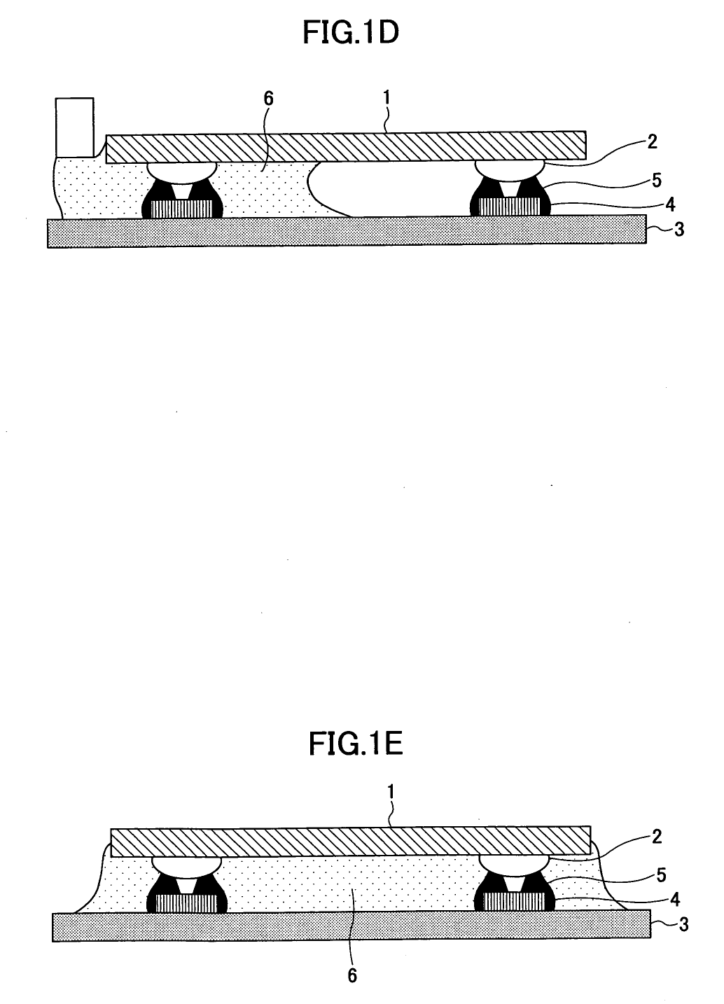

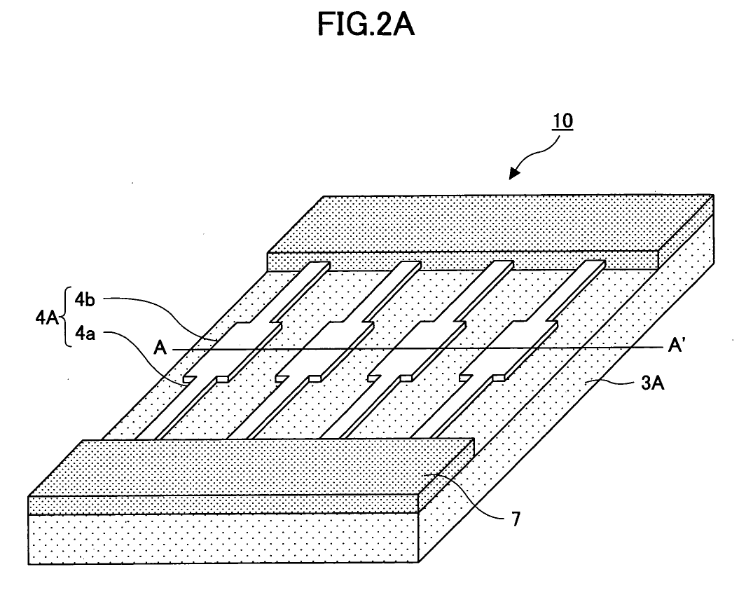

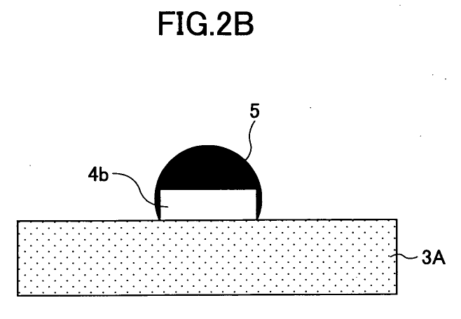

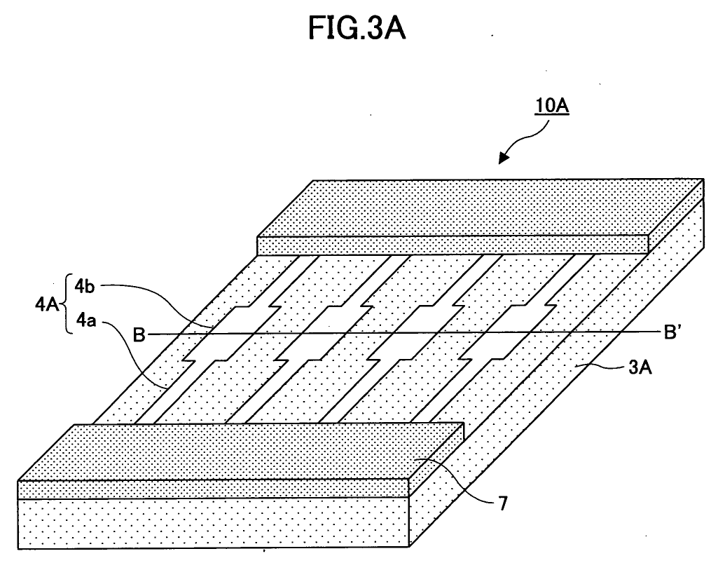

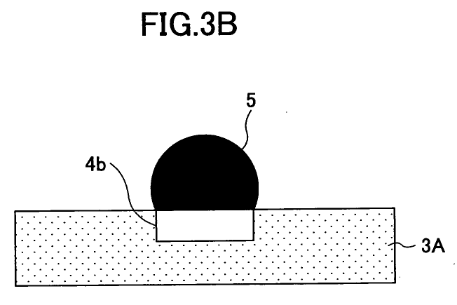

### DETAILED DESCRIPTION OF THE PREFERRED EMBODIMENTS

A description is given below, with reference to the accompanying drawings, of embodiments of the present invention.

[First Embodiment]

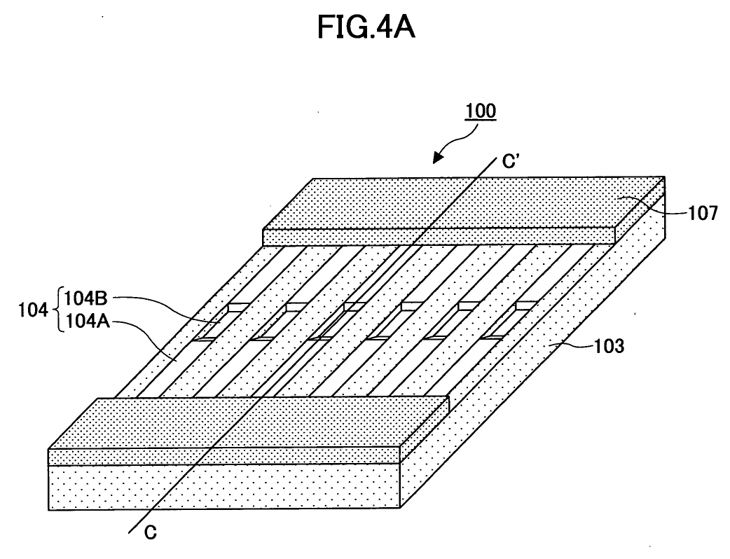

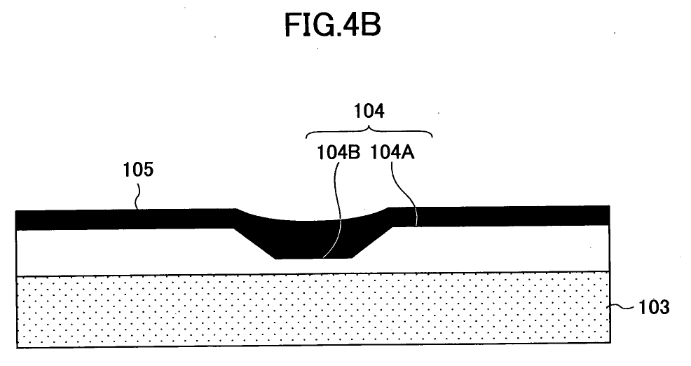

FIG. 4A is a schematic perspective view of part of a mounting board 100 according to a first embodiment of the present invention. Referring to FIG. 4A, the mounting board 100 according to this embodiment is a wiring board for mounting (connecting) a semiconductor chip having connection bumps formed thereon by flip-chip bonding. The mounting board 100 includes connection pads 104 and an insulating layer 103. The surface of each connection pad 104 is coated with solder. The connection pads 104 are to be electrically connected to the connection bumps of a semiconductor chip to be mounted. The insulating layer 103 surrounds each connection pad 104 so as to isolate the connection pads 104 from one another. In FIG. 4A, the solder is not graphically illustrated.

Each connection pad 104 includes a first region 104A and a second region 104B. The second region 104B is to be connected to a corresponding one of the connection bumps of the semiconductor chip to be mounted. The surface of the first region 104A is positioned substantially as high as the surface of the insulating layer 103. That is, the surface of the first region 104A and the surface of the insulating layer 103 are in substantially the same plane. The surface of the second region 104B is lower than the surface of the first region 104A. That is, the surface of the second region 104B is lower than the surface of the insulating layer 103. In other words, the surface of the second region 104B is positioned closer to the opposite surface of the insulating layer 103 than the surface of the first region 104A is. In other words, the surface of the second region 104B is vertically positioned, or positioned in the direction toward the semiconductor chip to be mounted, between a first surface of the insulating layer 103 formed in substantially the same plane as (substantially on a level with) the surface of the first region 104A and a second surface of the insulating layer 103 opposing the first surface. Further, the first region 104A and the second region 104B have substantially the same width. Accordingly, the connection pad 104 has a belt-like shape.

In a plan view, the connection pad 104 has a substantially rectangular (strip-like) shape. Further, the concave second region 104B is formed in the substantial center of the connection pad 104. Alternatively, the concave second region 104B may be formed in a part of the connection pad 104 other than the center thereof. The first region 104A is formed on each side of the second region 104B.

Therefore, when the solder with which the connection pad 104 is coated is melted, it is possible to efficiently concentrate the melted solder in the second region 104B to be connected to a connection bump of the semiconductor chip. Accordingly, unlike the above-described mounting boards 10 and 10A, there is no need to increase the width of part of a connection pad to be connected to a semiconductor chip.

Thus, according to the mounting board 100 of this embodiment, it is possible to make the width of a connection pad smaller and the pitch for disposing connection pads narrower than conventionally. Accordingly, it is possible to mount a semiconductor chip having a miniaturized circuit on the mounting board 100 by forming connection pads accommodating the miniaturized circuit of the semiconductor chip and a narrow pitch of the connection bumps of the semiconductor chip.

Further, a solder mask layer 107 having an opening is formed on the insulating layer 103, and each connection pad 104 is formed so as to have part thereof including the second region 104B exposed through the opening.

FIG. 4B is a cross-sectional view of the mounting board 100 of FIG. 4A taken along the line C-C′. In FIG. 4B, the same elements as those described above are referred to by the same reference numerals, and a description thereof is omitted. Referring to FIG. 4B, a coating layer 105 of solder is formed on the connection pad 104. The coating layer 105 is first formed on the connection pad 104 by, for example, plating so as to have a substantially uniform thickness of, for example, approximately 5 μm.

After forming the coating layer 105, the connection pad 104 (mounting board 100) is heated so as to melt the coating layer 105 (by reflowing), so that the coating layer 105 is reduced in thickness in the first region 104A, and is thicker in the second region 104B than in the first region 104A. That is, the coating layer 105 has a thickness suitable for mounting a semiconductor chip (connecting a connection bump) in the second region 104B.

According to the mounting board 100, for example, it is possible to form fine patterns where the connection pads 104 each has a width of approximately 10 to 15 μm and are disposed with a pitch of approximately 20 to 35 μm, so that it is possible to mount a semiconductor chip by flip-chip bonding without adjacent patterns being short-circuited through solder.

Preferably, the first region 104A is, for example, approximately 50 to 100 μm in length, and the second region 104B is, for example, approximately 50 μm in length.

For example, the connection pads 104 may be formed of a metal material such as Cu, and the insulating layer 103 may be formed of a so-called build-up resin (epoxy resin, polyimide resin, etc.). However, the connection pads 104 and the insulating layer 103 are not limited to those materials.

Further, FIG. 4A shows an enlarged view of part of the mounting board 100 on which the connection pads 104A are formed. The connection pads 104 are formed in correspondence to the connection bumps of a semiconductor chip. For example, the connection pads 104 are formed in correspondence to the four sides of a rectangular parallelepiped semiconductor chip at which sides pads are formed.

FIG. 5 is a schematic cross-sectional view of the entire mounting board 100. In FIG. 5, the same elements as those described above are referred to by the same reference numerals, and a description thereof is partly omitted.

Referring to FIG. 5, the mounting board 100 according to this embodiment includes interconnection parts 108A electrically connected to the connection pads 104. The interconnection parts 108 are configured so that a semiconductor chip to be mounted on a side of the mounting board 100 on which the connection pads 104 are formed (hereinafter referred to as “top side”) is connectable to a target of connection (such as a motherboard) on the opposite side (hereinafter, “bottom side”) of the mounting board 100.

Each of the interconnection parts 108 includes a via plug 108A connected to a corresponding one of the connection pads 104, and a pattern interconnection 108B formed on the bottom-side surface of the insulating layer 103 and corrected to the via plug 108A. Further, a solder mask layer 109 is formed to cover the bottom-side surface of the insulating layer 103, part of the pattern interconnection 108B, and the via plug 108A.

A coating layer 110 of solder is formed on part of the pattern interconnection 108B exposed through a corresponding opening of the solder mask layer 109. The interconnection part 108 is connectable to a target of connection such as a motherboard through the coating layer 110.

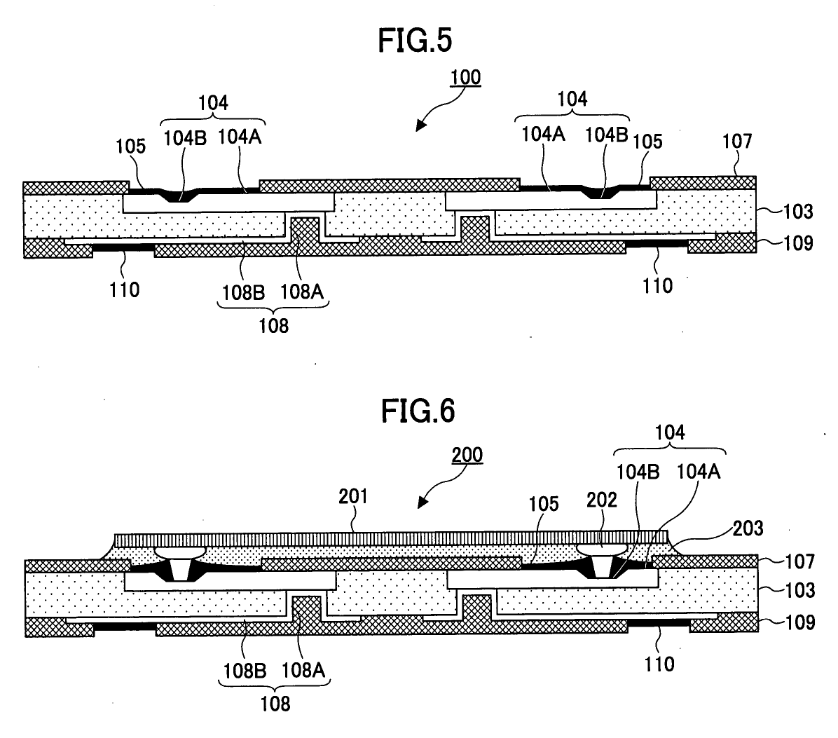

Further, FIG. 6 is a schematic cross-sectional view of a semiconductor device 200 having a semiconductor chip 201 mounted on the mounting board 100 by flip-chip bonding. In FIG. 6, the same elements as those described above are referred to by the same reference numerals, and a description thereof is omitted.

Referring to FIG. 6, the semiconductor device 200 has the semiconductor chip 201, having connection bumps (Au bumps) 202 formed thereon, mounted on the mounting board 100. For example, the connection bumps 202 are formed by Au wire bonding. In the second region 104B, the coating layer 105 is formed so as to rise toward the connection bump 202 side. This is because melted solder wets (comes into contact with) the connection bump 202 so as to concentrate on the connection bump 202 side because of surface tension. A description is given below of such a semiconductor device mounting method.

In the semiconductor device 200, it is possible to make smaller the width of each connection pad 104 connected to the semiconductor chip 201 and to make narrower the pitch with which the connection pads 104 are disposed than conventionally. Accordingly, it is possible to mount the semiconductor chip 201 having a miniaturized circuit on the mounting board 200 by forming the connection pads 104 accommodating the miniaturized circuit of the semiconductor chip 201 and a narrow pitch of the connection bumps 202 of the semiconductor chip 201.

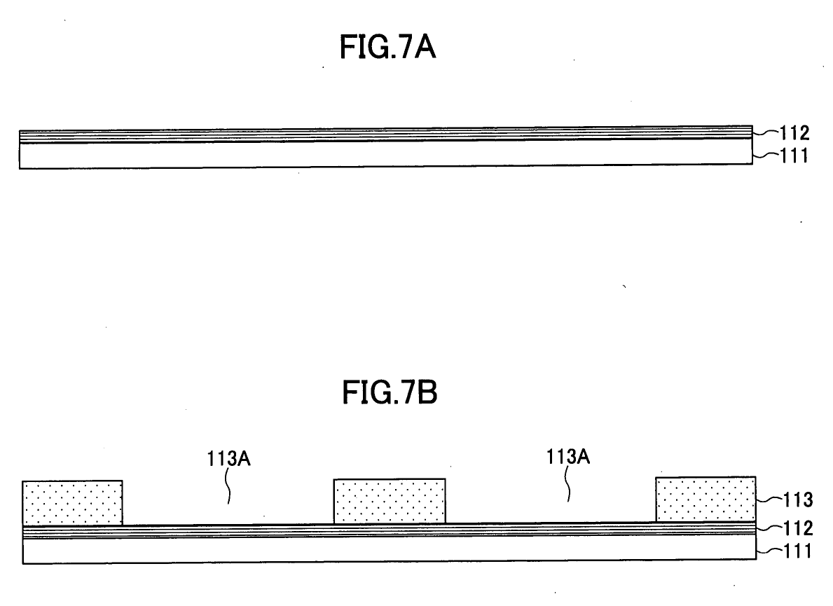

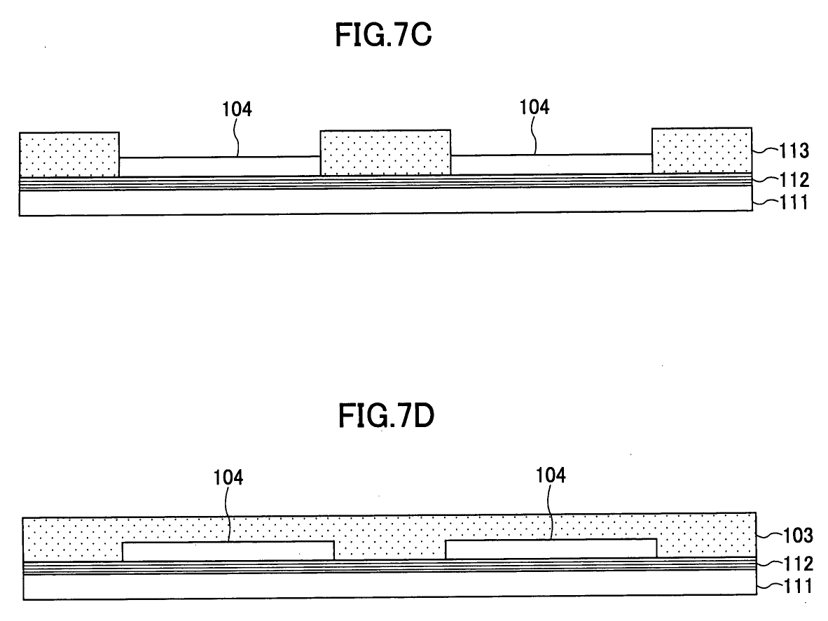

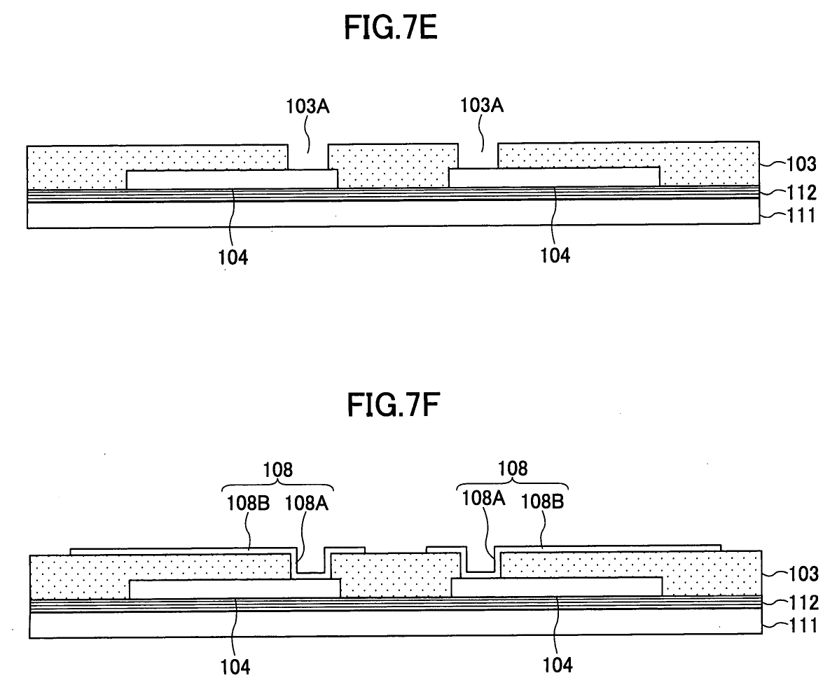

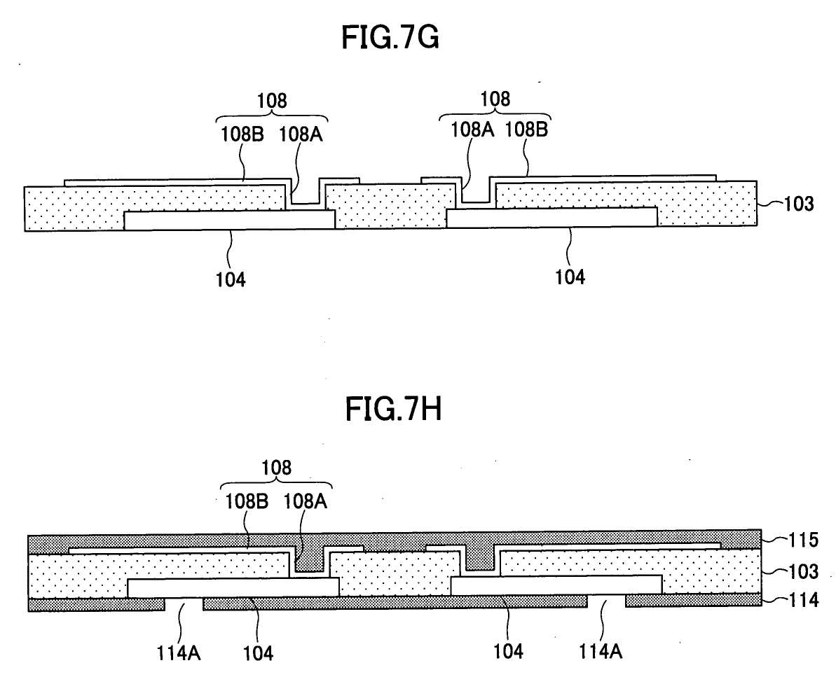

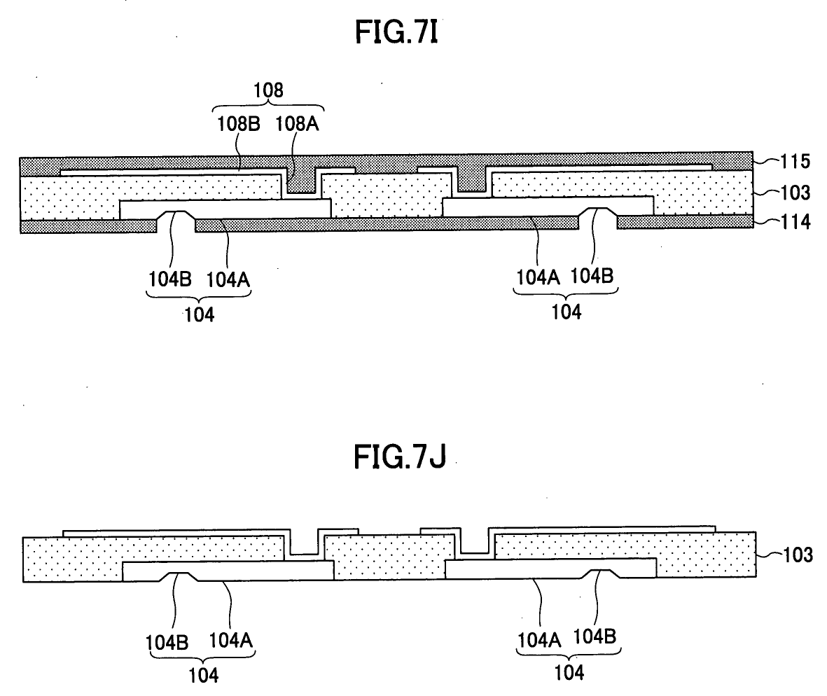

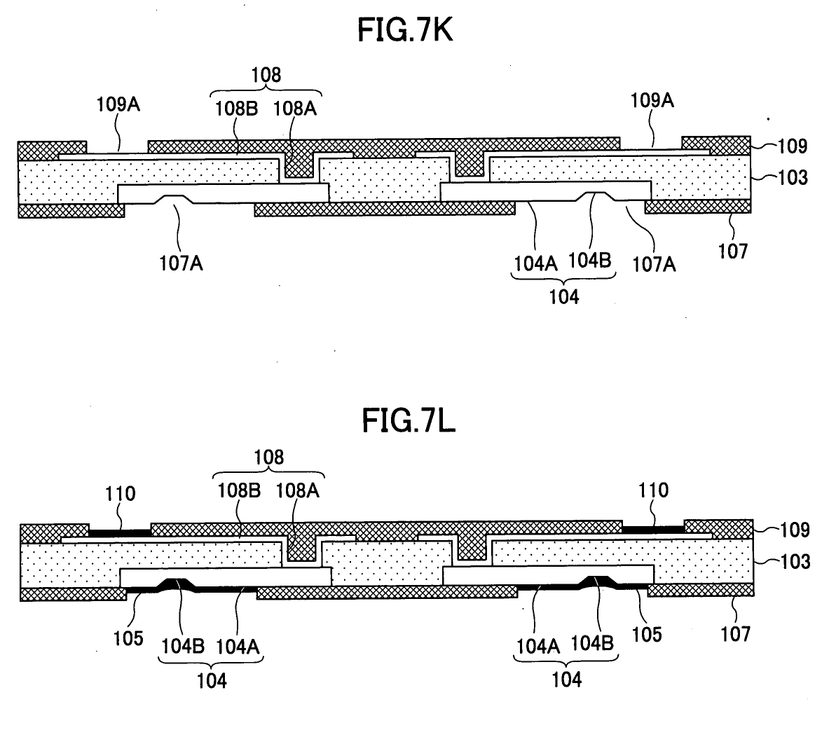

Next, a description is given, with reference to FIGS. 7A through 7L, of a method of manufacturing the mounting board 100. In the following drawings, the same elements as those described above are referred to by the same reference numerals, and a description thereof is partly omitted.

First, in the process shown in FIG. 7A, for example, an etch stop layer 112 of a Ni or Sn plating layer is formed on a support substrate 111 formed of Cu.

Next, in the process shown in FIG. 7B, a resist layer is formed on the etch stop layer 112 by laminating dry film resist, and the resist layer is patterned by photolithography, thereby forming a resist pattern 113 having openings 113A.

Next, in the process shown in FIG. 7C, the connection pad 104 of Cu is formed on the etch stop layer 112 in each opening 113A by, for example, plating.

Next, in the process shown in FIG. 7D, after removing the resist pattern 113, the insulating layer 103 of a so-called build-up resin such as epoxy resin or polyimide resin is formed by lamination so as to cover the connection pads 104.

Next, in the process shown in FIG. 7E, the via holes 103A are formed in the insulating layer 103 with, for example, a YAG laser so as to reach the connection pads 104.

Next, in the process shown in FIG. 7F, the via plug 108A connected to the corresponding connection pad 104 is formed on the inner wall of each via hole 103A and the pattern interconnection 108B connected to the via plug 108A is formed on the insulating layer 103 by, for example, Cu plating. As a result, the interconnection parts 108 are formed.

Next, in the process shown in FIG. 7G, the support substrate 111 and the etch stop layer 112 are removed by etching, so that the connection pads 104 are exposed.

Next, in the process shown in FIG. 7H, a resist layer is formed on the lower surface of the insulating layer 103 so as to cover the connection pads 104 by laminating dry film resist, and the resist layer is patterned by photolithography, thereby forming a resist pattern 114 having openings 114A. Further, part of each connection pad 104 is exposed through the corresponding opening 114A.

Further, it is preferable to form a resist layer 115 of dry film resist on the interconnection parts 108 in order to protect the interconnection parts 108.

Next, in the process shown in FIG. 7I, the part of each connection pad 104 exposed through the corresponding opening 114A is etched by wet etching (half etching), so that the second region 104B of the connection pad 104 is formed. Thus, the connection pads 104 each formed of the corresponding first and second regions 104A and 104B are formed.

Next, in the process shown in FIG. 7J, the resist pattern 114 and the resist layer 115 are removed.

Next, in the process shown in FIG. 7K, the solder mask layer 107 having openings 107A is formed so as to cover the connection pads 104. Part of each connection pad 104 including the corresponding second region 104B is exposed through the corresponding opening 107A.

Likewise, the-solder mask layer 109 having openings 109A is formed so as to cover the interconnection parts 108. Part of each pattern interconnection 108B is exposed through the corresponding opening 109A.

Next, in the process shown in FIG. 7L, the coating layer 105 of solder is formed on the surface of the part of each connection pad 104 exposed through the solder mask layer 107 by, for example, plating. Likewise, the solder coating layer 110 of solder is formed on the surface of the part of each pattern interconnection 108B exposed through the solder mask layer 109 by, for example, plating. Further, by performing reflowing on the coating layers 105 as required, it is possible to form the mounting board 100 described above with reference to FIG. 5.

According to the manufacturing method shown in FIGS. 7A through 7L, the insulating layer 103 and the connection pads 104 are formed on the flat support substrate 111, and the support substrate 111 is removed in a later process. Therefore, it is easy to form the surface of the insulating layer 103 and the surfaces of the first regions 104A of the connection pads 104 in substantially the same plane, which is preferable and suitable.

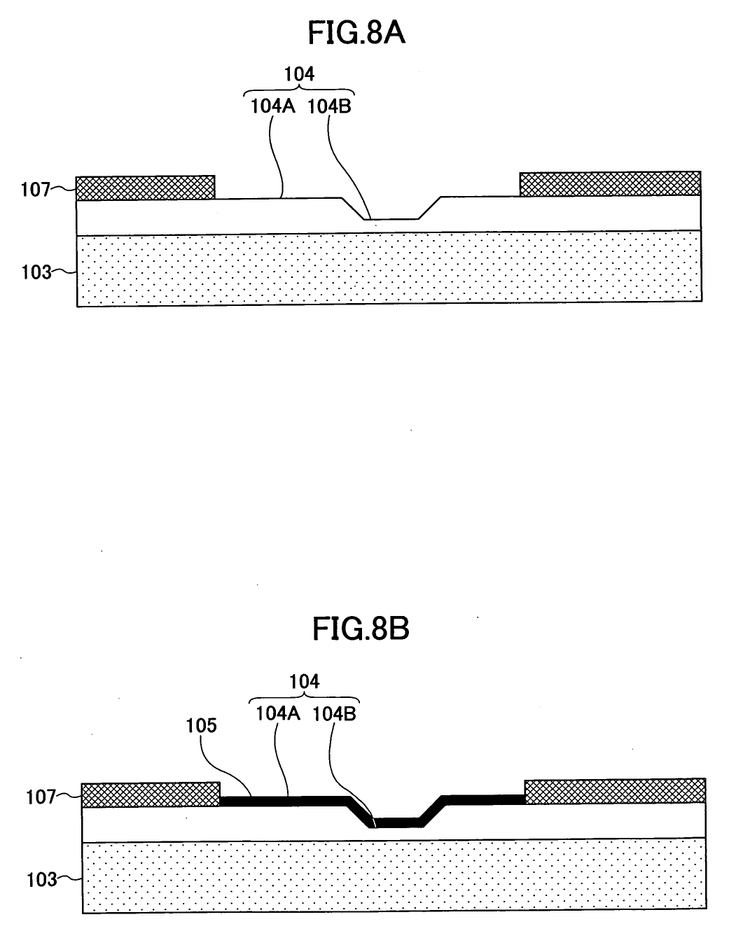

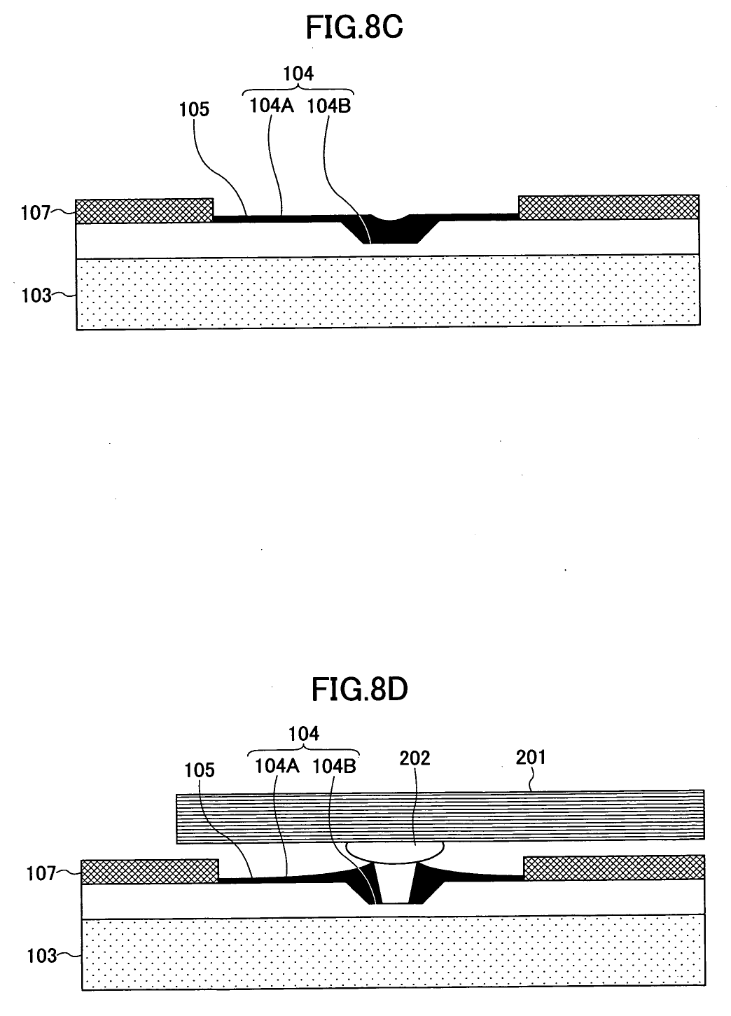

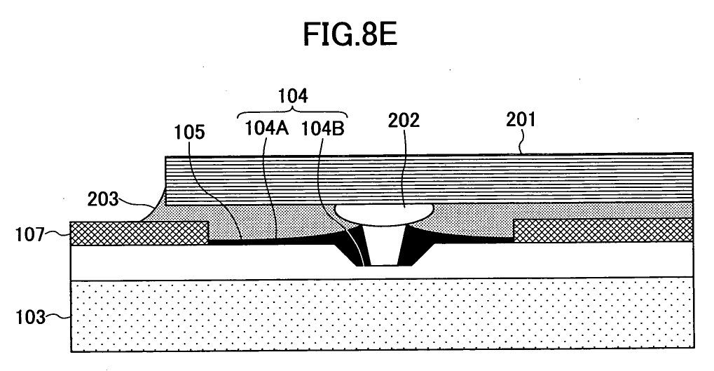

Next, a description is given, with reference to FIGS. 8A through 8E, of a method of forming the semiconductor device 200 shown in FIG. 6. In the following drawings, the same elements as those described above are referred to by the same reference numerals, and a description thereof is partly omitted.

First, FIG. 8A is an enlarged view of part of the neighborhood of one of the connection pads 104 in the above-described process shown in FIG. 7K. As shown in FIG. 8A, the first region 104A whose surface is substantially as high as the surface of the insulating layer 103, and the second region 104B to be connected to a corresponding connection bump of a semiconductor chip, whose surface is lower than that of the first region 104A, are formed in the connection pad 104. Further, the first region 104A is formed to have a height (thickness) of, for example, approximately 15 μm, and the second region 104B is formed to have a height (thickness) of, for example, approximately 6 to 8 μm. Further, the below-described processes of FIGS. 8B and 8C correspond to the above-described process of FIG. 7L.

In the process shown in FIG. 8B, the coating layer 105 of solder is formed on the surface of the connection pad 104. In the state shown in FIG. 8B, the coating layer 105 is formed to have substantially the same thickness (for example, approximately 5 μm) in the first region 104A and the second region 104B.

Next, in the process shown in FIG. 8C, the connection pad 104 (mounting substrate 100) is heated so as to melt (perform reflowing on) the solder, thereby causing the melted solder to concentrate at the second region 104B, so that the coating layer 105 is thin in the first region 104A and is thicker in the second region 104B than in the first region 104A.

Next, in the process shown in FIG. 8D, the semiconductor chip 201 is mounted on the mounting board 100 with the corresponding connection bump 202 being in contact with the second region 104B. In this case, the melted solder wets (comes into contact with) the connection bump 202. As a result, the melted solder concentrates on the connection bump 202 side of the second region 104B because of surface tension.

Next, in the process shown in FIG. 8E, an underfill layer 203 is formed between the semiconductor chip 201 and the mounting board 100, so that the above-described semiconductor device 200 shown in FIG. 6 can be formed.

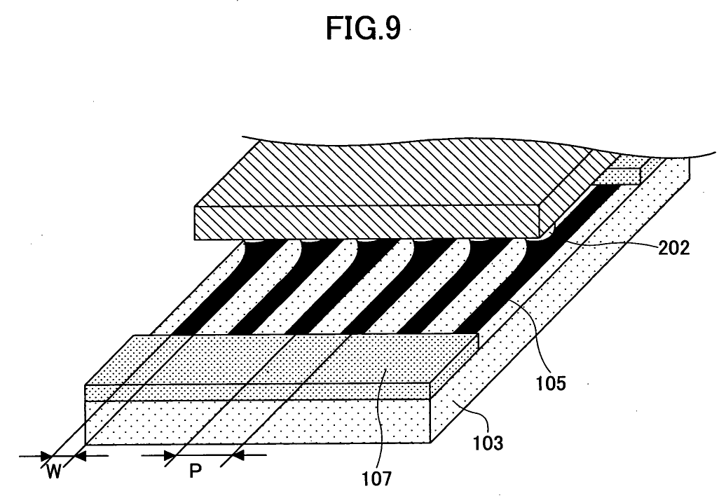

FIG. 9 is a schematic perspective view of the semiconductor device 200 shown in FIG. 6. In FIG. 9, the same elements as those described above are referred to by the same reference numerals, and a description thereof is omitted. Further, FIG. 9 shows an enlarged view of only the part of the semiconductor device 200 where some of the connection pads 104 are connected to the corresponding connection bumps 202. The structure where the connection pads 104 and the connection bumps 202 are connected is formed, for example, in correspondence to the four sides of the semiconductor chip 201.

According to the semiconductor device 200, the width W of each connection pad 104 is, for example, 10 μm, and the pitch P of the connection pads 104 (connection bumps 202) is, for example, 30 μm, so that the semiconductor chip 201 corresponding to a miniaturized semiconductor circuit can be mounted.

[Second Embodiment]

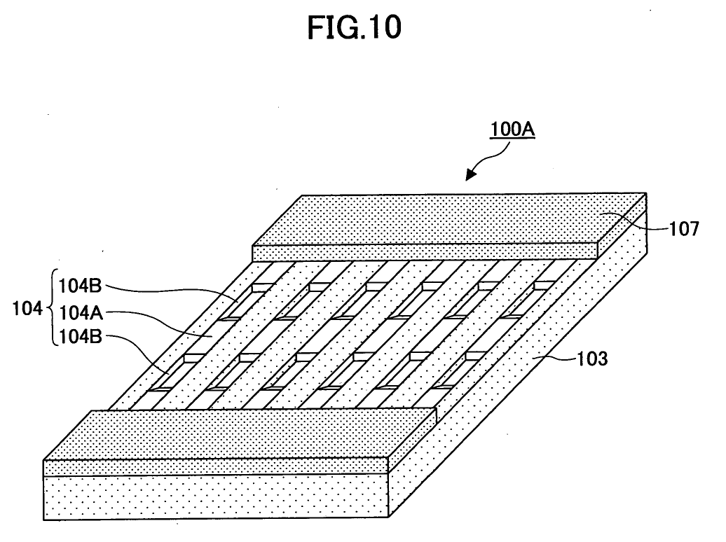

FIG. 10 is a schematic perspective view of a mounting board 100A according to a second embodiment of the present invention. In FIG. 10, the same elements as those described above are referred to by the same numerals, and a description thereof is omitted. FIG. 10 corresponds to FIG. 4A of the first embodiment. The second embodiment is the same as the first embodiment unless otherwise described.

Referring to FIG. 10, according to the mounting board 100A of this embodiment, each connection pad 104 has two second regions. 104B formed adjacently therein.

This corresponds to the case where the connection bumps of a semiconductor chip to be mounted are disposed alternately in different rows in a so-called staggered manner. Alternate disposition of the connection bumps of a semiconductor chip as described above is preferable because this disposition makes it possible to narrow the pitch of the connection bumps. In this case, it is also possible to dispose the second regions 104B of the connection pads 104 alternately in a staggered manner correspondingly. However, alignment of a mask is difficult in this case. Therefore, it is preferred to form the two second regions 104B adjacently in each connection pad as described above.

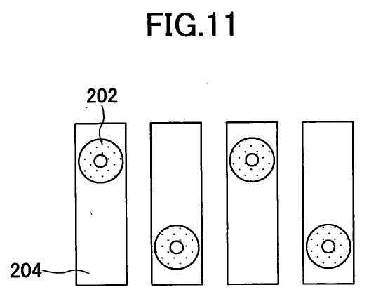

FIG. 11 is a diagram showing a formation pattern of pads 204 and the connection bumps 202 formed on a semiconductor chip to be mounted on the mounting substrate 100A of FIG. 10. Even if connection bumps are formed alternately on a semiconductor chip as shown in FIG. 11, it is possible to mount the semiconductor chip by employing the above-described mounting board 100A. It is apparent in this case that it is possible to form the mounting board 100A and a semiconductor device using the method shown in FIGS. 7A through 7L and the method shown in FIGS. 8A through 8E as in the case of the first embodiment.

The materials of and the methods of forming the connection pads, insulating layer, and the connection bumps shown in the above-described embodiments are merely examples, and the mounting boards and the semiconductor devices according to the above-described embodiments can be formed using other materials and methods.

According to one embodiment of the present invention, there is provided a mounting board on which a semiconductor chip having multiple connection bumps is to be mounted by flip-chip bonding, the mounting board including multiple connection pads to be electrically connected to the corresponding connection bumps, the connection pads having respective surfaces coated with solder; and an insulating layer configured to surround the connection pads and isolate the connection pads from each other, wherein each of the connection pads has a first region, and at least one second region to be connected to a corresponding one of the connection bumps, the first region having a surface substantially as high as a surface of the insulating layer and the at least one second region having a surface lower than the surface of the first region.

The above-described mounting board allows a semiconductor chip having a miniaturized circuit to be mounted thereon.

Additionally, it is preferable in the mounting board that each connection pad have multiple second regions formed therein because this facilitates mounting of a semiconductor chip having a miniaturized circuit.

According to one embodiment of the present invention, there is provided a semiconductor device including a semiconductor chip having multiple connection bumps; and a mounting board on which the semiconductor chip is mounted by flip-chip bonding, wherein the mounting board includes multiple connection pads to be electrically connected to the corresponding connection bumps, the connection pads having respective surfaces coated with solder; and an insulating layer configured to surround the connection pads and isolate the connection pads from each other, wherein each of the connection pads has a first region, and at least one second region to be connected to a corresponding one of the connection bumps, the first region having a surface substantially as high as a surface of the insulating layer and the at least one second region having a surface lower than the surface of the first region.

The above-described semiconductor device allows a semiconductor chip having a miniaturized circuit to be mounted therein.

Additionally, it is preferable in the semiconductor device that each connection pad have multiple second regions formed therein because this facilitates mounting of a semiconductor chip having a miniaturized circuit.

Additionally, it is preferable in the semiconductor device that the solder be formed to be thicker in the second region than in the first region because this increases the amount of solder in the connection parts of the semiconductor chip and the mounting board so as to ensure electrical and mechanical connections.

Thus, according to embodiments of the present invention, it is possible to provide a mounting board accommodating the miniaturization of the circuit of a semiconductor chip and a semiconductor device having a semiconductor chip mounted on the mounting board.

The present invention is not limited to the specifically disclosed embodiments, and variations and modifications may be made without departing from the scope of the present invention.

The present application is based on Japanese Priority Patent Application No. 2005-299206, filed on Oct. 13, 2005, the entire contents of which are hereby incorporated by reference.

What is claimed is:

1. A mounting board on which a semiconductor chip having a plurality of connection bumps is to be mounted by flip-chip bonding, the mounting board comprising:
a plurality of-connection pads to be electrically connected to the corresponding connection bumps, the connection pads having respective surfaces coated with solder; and
an insulating layer configured to surround the connection pads and isolate the connection pads from each other,
wherein each of the connection pads has a first region, and at least one second region to be connected to a corresponding one of the connection bumps, the first region having a surface substantially as high as a surface of the insulating layer and the at least one second region having a surface lower than the surface of the first region.

2. The mounting board as claimed in claim 1, wherein each of the connection pads has a plurality of the second regions formed therein.

3. A semiconductor device, comprising:
a semiconductor chip having a plurality of connection bumps; and
a mounting board on which the semiconductor chip is mounted by flip-chip bonding,
wherein the mounting board includes
a plurality of connection pads to be electrically connected to the corresponding connection bumps, the connection pads having respective surfaces coated with solder; and
an insulating layer configured to surround the connection pads and isolate the connection pads from each other,
wherein each of the connection pads has a first region, and at least one second region to be connected to a corresponding one of the connection bumps, the first region having a surface substantially as high as a surface of the insulating layer and the at least one second region having a surface lower than the surface of the first region.

4. The semiconductor device as claimed in claim 3, wherein each of the connection pads has a plurality of the second regions formed therein.

5. The semiconductor device as claimed in claim 3, wherein the solder is formed to be thicker in the at least one second region than in the first region.
